(19) United States
(12) Patent Application Publication
(10) Pub. No.: US 2007/0235168 A1
(43) Pub. Date: Oct. 11, 2007

(54) Air flow diversion device for dissipating heat from electronic components

(75) Inventors: Richard Chen, San Jose, CA (US); Alan Lee, Fremont, CA (US)

Correspondence Address: TROXELL LAW OFFICE PLLC, SUITE 1404, 5205 LEESBURG PIKE, FALLS CHURCH, VA, 22041, US

(73) Assignee: Super Micro Computer, Inc.

(21) Appl. No.: 11/400,181

(22) Filed: Apr. 10, 2006

(51) Int. Cl. H05K 7/20

(52) U.S. Cl. 165/124; 361/695

(57) ABSTRACT

An air flow diversion device for dissipating heat from electronic components, including: an air flow diversion member of predetermined height, wherein two or more left and right airway holes are defined in left and right side walls of the flow diversion member respectively, and a rear side of the flow diversion member is an open space, a connecting portion having a connecting hole is configured on the air flow diversion member, and the connecting portion can be fixedly bolted to a circuit board. An airflow is caused to follow a specific direction and diverted through the left and right airway holes into the open space, thereby enabling a relatively large amount of airflow having relatively high velocity to blow against circumferential surfaces of specific electronic components, thus achieving an efficient reduction in the working temperature of the specific electronic components.

### BACKGROUND OF THE INVENTION

(a) Field of the Invention

The present invention relates to an air flow diversion device for dissipating heat from electronic components, and more particularly to an air flow diversion device for use on circuit boards within an industrial host computer case, which uses a flow diversion member having airway holes and flow diversion side walls to cause the direction of airflow to align with and blow against specific electronic components on a circuit board, thereby achieving efficient heat dissipation and cooling of the specific electronic components.

(b) Description of the Prior Art

All circuit boards within conventional industrial host computer cases have various types of chips, computer memory and central processing units soldered thereon, and these electronic components are increasing along with the variety of functionality, for example, when a host computer needs to have utility to control many tool devices, distant monitoring systems, wireless remote control systems, and so on, the multitude and variety of electronic components must all be built onto the circuit board.

However, even though fans are installed in the vicinity of the circuit board to reduce the working temperature of the electronic components, direction the airflow blows is wide-ranging regardless of whether the fans are inducing a draught or ejecting air, and is probably too weak to achieve high-efficient cooling of the electronic components. Hence, heat dissipation of the electronic components is ineffective, resulting in a short serviceable life of the electronic components.

In light of the aforementioned, the subject of the present invention is to resolve and surmount existent technical difficulties to provide superior heat dissipation for specific electronic components on a circuit board, thereby increasing serviceable life of the electronic components.

### SUMMARY OF THE INVENTION

Accordingly, the primary objective of the present invention is to provide an air flow diversion device for dissipating heat from electronic components, which uses a flow diversion member disposed on a circuit board and selected electronic components are installed in an area close to the flow diversion member. A rapid airflow is caused to follow a specific direction, and is then diverted through airway holes defined in the flow diversion member, and these diverted airflows are further controlled to enable frontal blowing of the specific electronic components disposed close to the flow diversion device, thereby enabling a relatively large amount of airflow having relatively high velocity to blow against circumferential surfaces of the specific electronic components, thus achieving an efficient reduction in the working temperature of the specific electronic components.

To enable a further understanding of said objectives and the technological methods of the invention herein, brief description of the drawings is provided below followed by detailed description of the preferred embodiments.

### BRIEF DESCRIPTION OF THE DRAWINGS

FIG. 1 shows an elevational view of a flow diversion member according to the present invention.

FIG. 2 shows another elevational view of the flow diversion member according to the present invention.

FIG. 3 shows a cross-sectional view of the flow diversion member, electronic components and a circuit board installed interior of a computer case according to the present invention.

FIG. 4 shows an elevational schematic view of the flow diversion member, electronic components and the circuit board installed interior of a computer case according to the present invention.

FIG. 5 shows an overhead plan view of an embodiment according to the present invention.

### DETAILED DESCRIPTION OF THE PREFERRED EMBODIMENTS

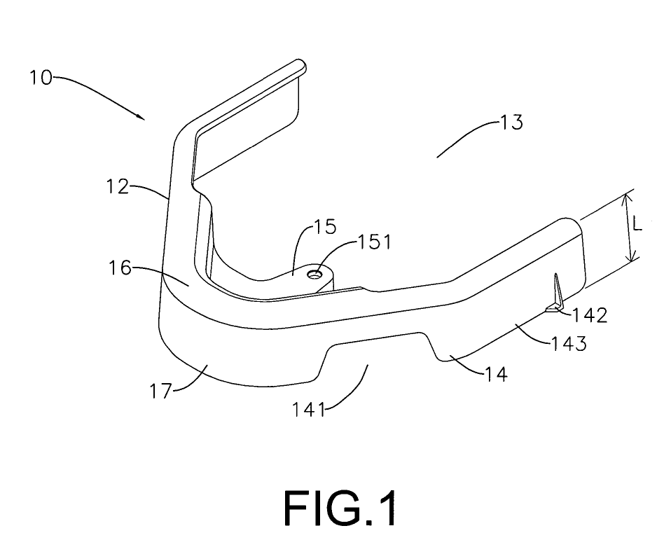

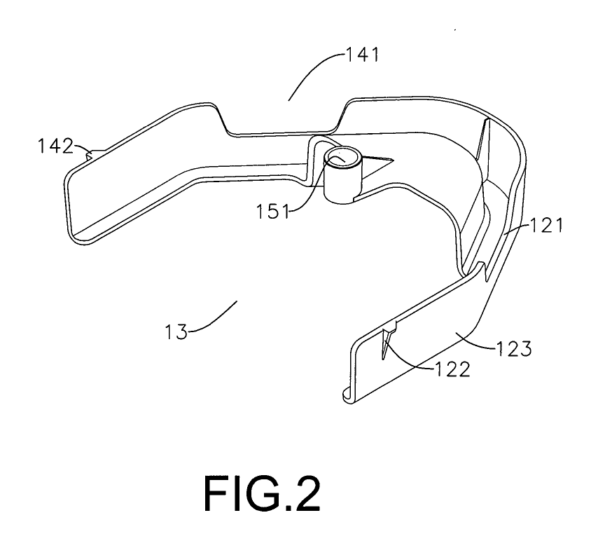

Referring to FIGS. 1 and 2, which show an air flow diversion device for dissipating heat from electronic components of the present invention, comprising:

an air flow diversion member 10 of predetermined height L, wherein two or more left and right airway holes 121, 141 are defined in the left and right side walls 12, 14 of the flow diversion member respectively, a rear portion of the flow diversion member 10 is an open space 13, and a connecting portion 15 having a connecting hole 151 is configured on the body of the flow diversion member 10; wherein the connecting portion 15 can be fixedly bolted to a circuit board 100.

An airflow following a specific direction passes through the left and right airway holes 121,141 and diverted into the open space 13.

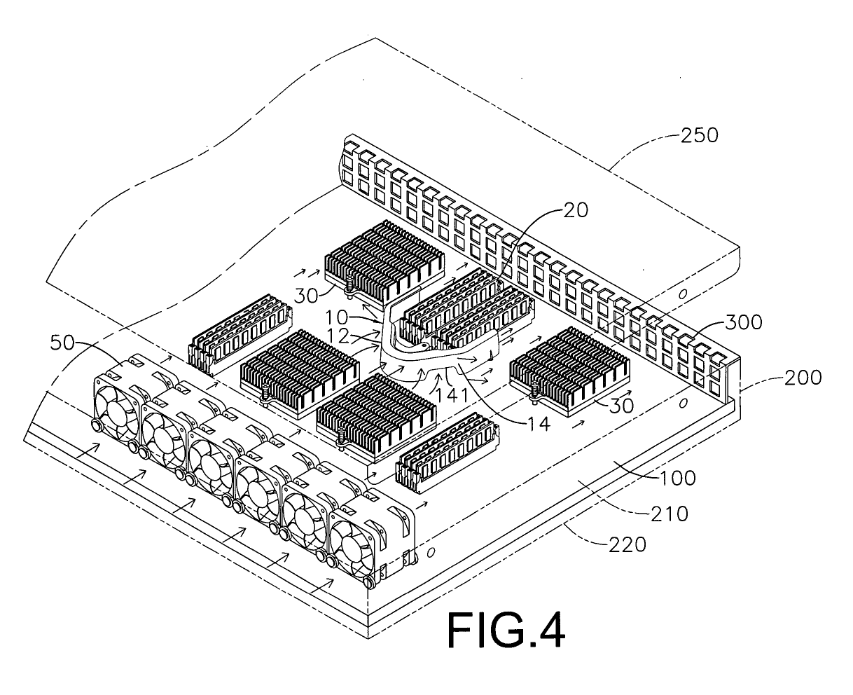

Referring to FIG. 4, wherein a first set of electronic components 20 are soldered to a surface of the circuit board 100 positioned in the open space 13. The left and right airway holes 12l, 141 divert and blow the airflow towards circumferential surfaces of the first set of electronic components 20 positioned in the open space 13, thereby dissipating heat therefrom.

Referring to FIGS. 1 and 2, wherein a circular arc wall 17 of smaller area is formed at a front end of the flow diversion member 10, and the left and right side walls 12, 14 having oblique surfaces extend from two sides of the circular arc wall 17, and straight walls 123, 143 extend from rear ends of the left and right side walls 12, 14 respectively. The connecting portion 15 extends from a rear side of the circular arc wall 17 as an integrated body thereof.

Referring to FIG. 4, wherein second sets of electronic components 30, (30) are soldered to the circuit board 100 close to the left and right side walls 12, 14. The airflow diverted by the left and right side walls 12, 14 enable lateral blowing of the second sets of electronic components 30, (30).

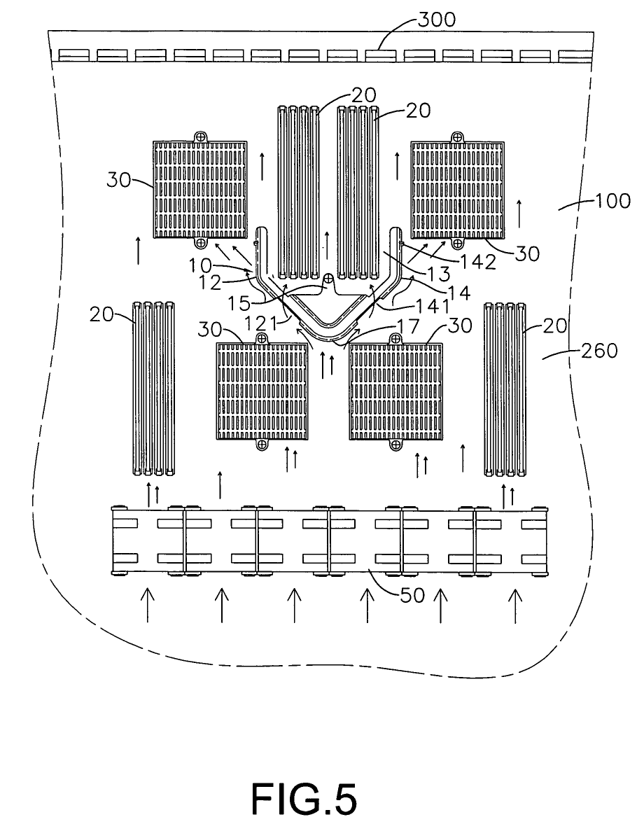

Referring to FIGS. 4 and 5, wherein a set of fans 50 are installed on the circuit board 100 and positioned in front of the flow diversion member 10, which induce a draught state and enable frontal blowing of the flow diversion member 10 by a rapid airflow.

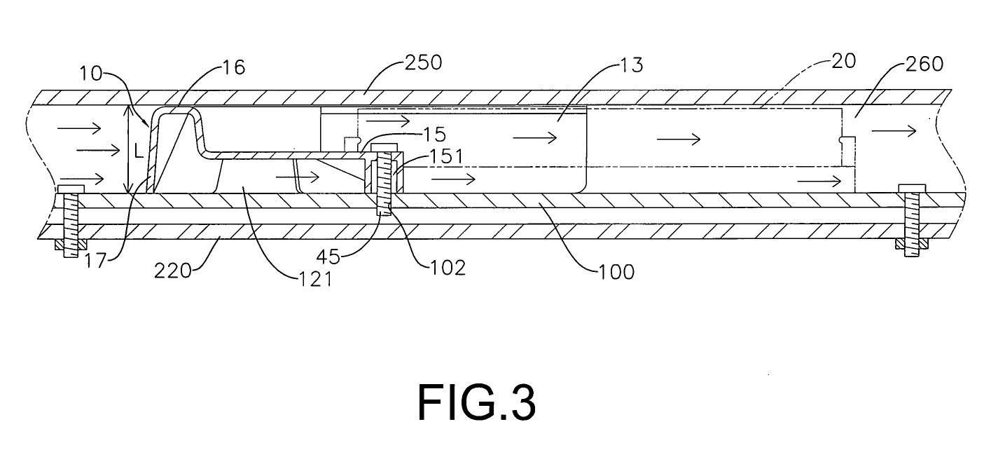

Referring to FIG. 3, wherein the connecting hole 151 defined in the connecting portion 15 enables a bolt 45 to penetrate therethrough and bolt into a bolt hole 102 pre-defined in the circuit board 100.

Protruding ribs 122, 142 are respectively configured on the straight walls 123, 124 that extend from the rear ends of the left and right side walls 12, 14, which are used to increase stress strength of the flow diversion member 10.

Referring to FIGS. 3 and 4, wherein the circuit board 100 is fixedly joined to a surface of an underplate 220 of a lower base 210 of a computer case 200.

The computer case 200 is provided with an upper cover 250 that covers the lower base 210, and space between the upper cover 250 and the lower base 210 forms a passageway 260 that enables a fast flow of air therethrough. The flowing air enters one end of the passageway 260 and flows out another end thereof.

A surface 16 of the flow diversion member 10 abuts against an undersurface of the upper cover 250.

Referring to FIGS. 1 and 2, which show a flow diversion member 10 of the present invention, which from an overhead view assumes a slight V-shape, wherein a circular arc wall 17 of the flow diversion member 10 assumes a slightly arc-shaped surface, and left and right side walls 12, 14 extend out from left and right sides of the circular arc wall 17 respectively. The left and right side walls 12, 14 are formed as oblique surfaced extended walls, while straight walls 123, 143 extend from ends of the left and right side walls 12, 14 respectively as integrated bodies thereof. The left and right airway holes 121, 141 are defined in the left and right side walls 12, 14 respectively, and an open space 13 is formed at a rear of the left and right airway holes 121, 141. The flow diversion member 10 is of appropriate height L.

Referring to FIG. 3, wherein a bolt hole 102 is pre-defined in a circuit board 100 of a host computer 100. A bolt 45 penetrates a connecting hole 151 and bolts into the bolt hole 102, thereby fixedly positioning the flow diversion member 10 onto the circuit board 100. A selected first set of electronic components 20 can be chips, computer memory, central processing units, air-cooling fins, and so on, which are fixedly soldered onto the circuit board 100, and the entire first set of electronic components 20 is positioned within the open space 13, as depicted in FIG. 4, which also shows an upper cover 250 being used to cover a lower base 210. An undersurface of the upper cover 250 overlays a surface 16 of the flow diversion member 10.

Referring to FIGS. 4 and 5, second sets of electronic components 30, (30) can be chips, computer memory, central processing units, air-cooling fins, and so on, which are respectively fixedly soldered onto the circuit board 100 lateral to and at appropriate distances from the left and right side walls 12, 14 of the flow diversion member 10. At least more than one fan 50 is installed on a side of the circuit board 100 appropriately positioned so as to be directly in front of the first set of electronic components 20 and the second sets of electronic components 30, (30). The fans 50 draw air from outside the lower base 210, which is then rapidly blown towards the first set of electronic components 20, the second sets of electronic components 30, (30) and the flow diversion member 10, whereafter the air is flow diverted out a mesh 300 at a rear side of the lower base 210. A passageway 260 formed between the upper cover 250 and an underplate 220 enables rapid air current flow in a specific direction therethrough.

Referring to FIG. 4, when an airflow is blown towards the left and right side walls 12, 14 of the flow diversion member 10, because the left and right side walls 12, 14 are formed as oblique surfaced walls, thus, they are able to divert or refract the airflow into left and right side area spaces of the flow diversion member 10, within which the second sets of electronic components 30, (30) are appropriately fitted. Hence, the diverted or refracted airflow blowing onto the second sets of electronic components 30, (30) enables efficient cooling of the working temperature of the second set of electronic components 30, (30) and dissipating of heat therefrom.

Referring to FIGS. 4 and 5, velocity of the airflow increases when a part the rapid airflow passes through the left and right airway holes 121, 141 perforations, and the airflows from the two left and right airway holes 121, 141 converge within the open space 13. Hence, the relatively faster airflow is able to rapidly blow and pass over circumferential surfaces of the first set of electronic components 20 installed within the open space 13, thereby efficiently cooling the working temperature of the first set of electronic components 20 and improving serviceable life thereof.

Referring again to FIGS. 1 and 2, wherein protruding ribs 122, 142 configured on the flow diversion member 10 increase stress strength of the flow diversion member 10, thereby preventing deformation thereof when blown on by a rapid airflow. Furthermore, referring again to FIG. 4, the circuit board 100 is installed on the underplate 220 inside of the lower base 210. The upper cover 250 is fixedly positioned onto the lower base 210, thereby enabling the space between the upper cover 250 and the lower base 210 to form the passageway 260 that allows an airflow to pass therethrough. When the fans 50 are actuated, a rapid airflow flows through the passageway 260 and out the mesh 300 configured at another end of the passageway 260. Furthermore, the surface 16 of the flow diversion member 10 abuts against the undersurface of the upper cover 250, thereby enabling frontal blowing of the flow diversion member 10 by the rapid airflow.

It is of course to be understood that the embodiments described herein are merely illustrative of the principles of the invention and that a wide variety of modifications thereto may be effected by persons skilled in the art without departing from the spirit and scope of the invention as set forth in the following claims.

What is claimed is:

1. An air flow diversion device for dissipating heat from electronic components, comprising:
an air flow diversion member of predetermined height, wherein two or more left and right airway holes are defined in left and right side walls of the flow diversion member respectively, and a rear side of the flow diversion member is an open space, a connecting portion having a connecting hole is configured on the air flow diversion member, the connecting portion can be fixedly bolted to a circuit board;
an airflow is caused to follow a specific direction, and is then diverted through the left and right airway holes into the open space;
a first set of electronic components are soldered to a surface of the circuit board and positioned within the open space,
airflows diverted through the left and right airway holes blows over circumferential surfaces of the first set of electronic components, thereby providing a heat dissipating operation thereon

2. The air flow diversion device for dissipating heat from electronic components according to claim 1, wherein a front end of the flow diversion member is a circular arc wall of relatively small area, and the left and right side walls having oblique surfaces respectively extend from two sides of the circular arc wall, and straight walls respectively extend from rear ends of the left and right side walls; the connecting portion extends from a rear side of the circular arc wall as an integrated body thereof.

3. The air flow diversion device for dissipating heat from electronic components according to claim 1, wherein second sets of electronic components are soldered to the circuit board close to the left and right side walls, and airflows diverted by the left and right side walls enable lateral blowing of the second sets of electronic components.

4. The air flow diversion device for dissipating heat from electronic components according to claim 1, wherein a set of fans are installed on the circuit board and positioned in front of the flow diversion member, which induce a draught state and enable frontal blowing of the flow diversion member by a rapid airflow.

5. The air flow diversion device for dissipating heat from electronic components according to claim 1, wherein the connecting hole defined in the connecting portion enables a bolt to penetrate therethrough and bolt into a bolt hole pre-defined in the circuit board 100.

6. The air flow diversion device for dissipating heat from electronic components according to claim 1, wherein protruding ribs are configured on the straight walls to increase stress strength of the flow diversion member.

7. The air flow diversion device for dissipating heat from electronic components according to claim 1, wherein the circuit board is fixedly joined to a surface of an underplate of a lower base of a computer case;
wherein the computer case is provided with an upper cover that covers the lower base, and space between the upper cover and the lower base forms a passageway that enables a fast flow of air therethrough, and the flowing air enters one end of the passageway and flows out another end thereof;
wherein a surface of the flow diversion member abuts against an undersurface of the upper cover.
